(19) United States
(12) Patent Application Publication
(10) Pub. No.: US 2026/0052880 A1
(43) Pub. Date: Feb. 19, 2026

(54) ELECTRONIC DEVICE INCLUDING A DISPLAY PANEL AND ADHESIVE GROUP

(71) Applicant: SAMSUNG DISPLAY CO., LTD., YONGIN-SI (KR)

(72) Inventors: ONNURI KIM, Yongin-si (KR); YEJIN KIM, Yongin-si (KR); SEOHYEON CHOI, Yongin-si (KR); SANG-GU LEE, Yongin-si (KR)

(21) Appl. No.: 19/067,285

(22) Filed: Feb. 28, 2025

(30) Foreign Application Priority Data
Aug. 16, 2024 (KR) 10-2024-0109882

(51) Int. Cl. H10K 59/80; H10K 59/12

(52) U.S. Cl. CPC H10K 59/8722; H10K 59/1201; H10K 59/8792

(57) ABSTRACT

An electronic device according to an embodiment of the present disclosure includes a display panel, an adhesive group and a window member. The adhesive group is disposed on the display panel defined with a display area and a non-display area surrounding at least a portion of the display area. The window member is disposed on the adhesive group. The adhesive group includes a first adhesive dam, a second adhesive dam and an adhesive layer. The first adhesive dam has at least a portion overlapping with the non-display area. The second adhesive dam covers a portion of the first adhesive dam and has at least a portion overlapping with the non-display area. The adhesive layer covers a portion of the first adhesive dam and a portion of the second adhesive dam and overlaps with the display area. The display area and the window member are attached by the adhesive group.

### CROSS-REFERENCE TO RELATED APPLICATIONS

This application claims priority under 35 U.S.C § 119 to Korean Patent Application No. 10-2024-0109882, filed on Aug. 16, 2024, in the Korean Intellectual Property Office, the contents of which are incorporated by reference herein in its entirety.

### BACKGROUND

### 1. Technical Field

The present disclosure relates to an electronic device including a display panel and an adhesive group, and a manufacturing method of the electronic device, and more specifically to an electronic device configured to provide light emitted near a periphery of a display panel more normally, and a manufacturing method thereof.

### 2. Description of Related Art

Optically clear adhesives and optically clear resins are examples of adhesives allowing transmission of visible light. The optically clear adhesive and the optically clear resin may be used in an electronic device including a display panel. For example, the optically clear adhesive and the optically clear resin may be disposed on the display panel to attach another element to the display panel.

### SUMMARY

An object of the present disclosure relates to an electronic device configured to provide light emitted near a periphery of a display panel more normally, with an area near the periphery of the display panel less covered, and with a display area of the display panel having an increased size, and a manufacturing method of the electronic device.

An electronic device according to an embodiment of the present disclosure may include a display panel, an adhesive group and a window member. The display panel may be defined with a display area and a non-display area surrounding at least a portion of the display area. The adhesive group may be disposed on the display panel. The window member may be disposed on the adhesive group. The adhesive group may include a first adhesive dam, a second adhesive dam and an adhesive layer. The first adhesive dam may have at least a portion overlapping with the non-display area. The second adhesive dam may cover a first portion of the first adhesive dam and have at least one portion overlapping with the non-display area. The adhesive layer may cover the first portion of the first dam and a portion of the second adhesive dam and overlap with the display area.

In an embodiment of the present disclosure, the second adhesive dam may be disposed on an outer surface of than the first adhesive dam disposed away from the display area.

In an embodiment of the present disclosure, the second adhesive dam exposes a second portion of the first adhesive dam.

In an embodiment of the present disclosure, the first adhesive dam may have a first height. The second adhesive dam may have a second height that is greater than the first height. The adhesive layer may have a third height that is the second height or greater.

In an embodiment of the present disclosure, the first height may be about 0.2 times and about 0.4 times the third height. The second height may be about 0.8 times and about 1.0 times the third height.

In an embodiment of the present disclosure, a contact angle of the second adhesive dam may be greater than a contact angle of the first adhesive dam.

In an embodiment of the present disclosure, each of the first adhesive dam, the second adhesive dam and the adhesive layer may include a photocurable material. The first adhesive dam may have a first degree of cure. The second adhesive dam may have a second degree of cure that is less than the first degree of cure. The adhesive layer may have a third degree of cure that is less than the second degree of cure.

In an embodiment of the present disclosure, the first degree of cure may be between about 95% and 99%. The second degree of cure may be between about 93% and 94%. The third degree of cure may be between about 91% and 92%.

In an embodiment of the present disclosure, a degree of cure of a portion of the adhesive layer overlapping with the display area may be substantially the same as a degree of cure of a portion overlapping with the non-display area.

In an embodiment of the present disclosure, each of the first adhesive dam, the second adhesive dam, and the adhesive layer may include a pressure sensitive adhesive.

In an embodiment of the present disclosure, the window member may include a light transmission part and a light blocking part. The light penetrating part may overlap with the adhesive layer and be configured to transmit light emitted from the display panel. The light blocking part may overlap with the first adhesive dam and the second adhesive dam and be configured to block light emitted from the display panel.

The electronic device according to an embodiment of the present disclosure may include a display panel, an adhesive group and a window member. The display panel may be defined with a display area and a non-display area surrounding at least a portion of the display area. The adhesive group may be disposed on the display panel. The window member may be disposed on the adhesive group. The adhesive group may include a first adhesive dam, a second adhesive dam and an adhesive layer. The first adhesive dam may extend along a boundary portion between the display area and the non-display area. The second adhesive dam may be disposed in at least a portion of the non-display area and may cover a first portion of the first adhesive dam and extend along the first adhesive dam. The adhesive layer may have at least a portion surrounded by the first adhesive dam and the second adhesive dam and cover the first portion of the first adhesive dam and a portion of the second adhesive dam.

In an embodiment of the present disclosure, the second adhesive dam may be disposed on an outer surface of the first adhesive dam disposed away from the display area. The second adhesive dam may expose a second portion of the first adhesive dam.

In an embodiment of the present disclosure, the first adhesive dam may have a first height. The second adhesive dam may have a second height that is greater than the first height. The adhesive layer may have a third height that is equal to or greater than the second height.

In an embodiment of the present disclosure, a contact angle of the second adhesive dam may be greater than a contact angle of the first adhesive dam.

In an embodiment of the present disclosure, each of the first adhesive dam, the second adhesive dam and the adhesive layer may include a photocurable material. The first adhesive dam may have a first degree of cure. The second adhesive dam may have a second degree of cure that is less than the first degree of cure. The adhesive layer may have a third degree of cure that is less than the second degree of cure.

In an embodiment of the present disclosure, each of the first adhesive dam, the second adhesive dam and the adhesive layer may include a pressure sensitive adhesive.

A manufacturing method of the electronic device according to an embodiment of the present disclosure may include providing a display substrate including a display panel defined with a display area and a non-display area surrounding at least a portion of the display area, disposing a first dam having at least a portion overlapping with the non-display area and including a photocurable material, performing a first curing of the first adhesive dam, disposing a second adhesive dam covering a portion of the first adhesive dam, having at least a portion overlapping with the non-display area and including a photocurable material, performing a second curing of the second adhesive dam and the first adhesive dam, forming an adhesive layer covering the portion of the first adhesive dam and a portion of the second adhesive dam, overlapping with the display area and including a photocurable material, performing a third curing of the adhesive layer, the second adhesive dam and the first adhesive dam, and bonding a window member to the display substrate using the first adhesive dam, the second adhesive dam and the adhesive layer.

In an embodiment of the present disclosure, an amount of the light irradiated in performing the third curing may be greater than an amount of the light irradiated in performing the first curing and an amount of the light irradiated in performing the second curing.

In an embodiment of the present disclosure, a viscosity of the first adhesive dam, as disposed, may be between about 5 cP and about 40 cP. A viscosity of the second adhesive dam, as disposed, may be between about 5 cP and about 40 cP. A viscosity of the adhesive layer, as formed, may be between about 5 cP and 40 cP.

In an embodiment of the present disclosure, even though an optically clear resin is used, light emitted near an edge of a display panel may be normally provided to an outside. For example, a distortion of light emitted near an edge of a display panel may be reduced.

Therefore, a size of a light blocking part covering the light emitted at a periphery of the display panel may be reduced, and the light emitted near at the periphery of the display panel may be transmitted to the outside. For example, a display panel may have a greater display area. Further, a manufacturing method thereof may be provided.

### BRIEF DESCRIPTION OF THE DRAWINGS

These and/or other features will become apparent and more readily appreciated from the following description of example embodiments, taken in conjunction with the accompanying drawings in which:

FIG. 1 is an exemplary schematic view of a display device according to an embodiment of the present disclosure;

FIG. 2 is an exemplary cross-sectional view of a display device according to an embodiment of the present disclosure;

FIG. 3A, FIG. 3B and FIG. 3C are exemplary cross-sectional views of a display substrate according to an embodiment of the present disclosure;

FIG. 4 is an exemplary illustration of a display panel according to an embodiment of the present disclosure;

FIG. 5 is an exemplary illustration of an input sensor circuit according to an embodiment of the present disclosure;

FIG. 6 is an exemplary plan view of a display substrate according to an embodiment of the present disclosure;

FIG. 7 is an exemplary magnified view of a portion marked with AA shown in FIG. 2 by omitting a window member;

FIG. 8 is an exemplary magnified view of a portion marked with AA shown in FIG. 2;

FIG. 9 is an exemplary magnified view of a portion marked with BB shown in FIG. 3A;

FIGS. 10A through 10D are exemplary illustrations of a process of forming an adhesive group on an adhesive surface according to an embodiment of the present disclosure;

FIGS. 11 through 17 are exemplary magnified views of a portion marked with AA shown in FIG. 2 by omitting a window member;

FIG. 18 is an exemplary flow diagram of a manufacturing method of an electronic device according to an embodiment of the present disclosure;

FIGS. 19A through 19D are schematic cross-sectional views of a manufacturing method according to an embodiment of the present disclosure; and

FIG. 20 is a diagram illustrating an electronic device according to an embodiment of the present invention.

FIG. 21 and FIG. 22 are diagrams illustrating electronic devices to which the display device according to an embodiment of the present disclosure is applied.

### DETAILED DESCRIPTION

Hereinafter, embodiments of the inventive concept will be described with reference to the attached drawings. The same reference numerals may refer to the same elements throughout the specification. Aspects of the inventive concept may be embodied in different forms and should not be construed as limited to embodiments set forth herein. Rather, the present disclosure shall be construed to encompass all forms, permutations, equivalents and substitutes covered by the technical ideas and scope of the present disclosure. Accordingly, embodiments are merely described herein, by referring to the figures, to explain features of the present disclosure.

In the accompanying drawings, ratios and dimensions of the elements may not be to exact scale and may have been exaggerated for the benefit of effective explanation of the technical features associated with these elements. Any reference to “and/or” shall be construed to include one or more combinations that can be defined by relevant elements. When a device or a layer is “above” another device or layer, the device or the layer may be directly above the other device or layer or have yet another device or layer interposed in the middle. Meanwhile, when a device is “directly above” another device, yet another device or layer is not interposed in the middle. A same reference numeral is used for the same element over the description.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

According to an embodiment of the present disclosure, an adhesive group may be disposed on a display substrate and may have a structure that facilitates a reduction in a width of a light blocking part of a window member, and an increase in a size of the display area. In at least one embodiment, the light blocking part may be omitted and a sub adhesive group may be disposed on a display module and may have a structure that facilitates a reduction in a width of the non-display area, and an increase in a size of the display area.

FIG. 1 is an exemplary schematic view of a display device DD according to an embodiment of the present disclosure.

FIG. 1 is an exemplary illustration in which a smartphone is a display device DD. Yet, a use of the display device DD is not limited to what is illustrated in FIG. 1. For example, the display device DD may be a tablet, a laptop, a TV, a head mounted display, or a digital watch.

Furthermore, the display device DD may be a part of a transportation means, such as a car, bicycle, motorcycle, train, boat, or airplane. For example, the display device DD may be positioned, relative to a driver of a vehicle, in front of the steering wheel in the vehicle and used for displaying instrument panel information such as the vehicle's speed. The display device DD may be also positioned on the dashboard of a vehicle to display control interfaces, audio settings, temperature, road conditions, or video information. The display device DD may be positioned in an interior and on either side of the front seats and may used as digital side-view mirrors. The display device DD may be configured to display images captured from the vehicle's exterior, and may be used as a digital rear-view mirror. The display device DD may be mounted on the back of the driver's and/or passenger's seats and visible to a rear-seat passenger, and may used for displaying images for view by the rear-seat passengers.

The display device DD may be defined with a display area DA and a non-display area NDA. The display area DA may be configured to display an image and detect an input of a user.

The display area DA may be parallel to a plane defined by a first directional axis DR1 and a second directional axis DR2.

A normal direction of the display area DA, e.g., a direction of a thickness of the display device DD, may be defined by a third directional axis DR3. A front surface (or an upper surface) and a back surface (or a lower surface) may be distinguished by the third directional axis DR3. However, directions pointed by the first through the third directional axes are merely a relative concept and may be converted into other directions. Hereinafter, the first through the third directions are directions pointed by the first through the third directional axes, respectively, and are described with the same figure references. A shape of the display area DA shown in FIG. 1 is an example, and other shapes of the display area DA may be provided. For example, the display area DA may have a curved shape including a portion curved to a side. In addition, the display area DA may have a polygonal shape, a shape with a vertex of a polygon rounded to a curve or a circular shape, or a curved or rounded shape.

The non-display area NDA may be an area adjacent to the display area DA that does not display an image. A bezel area of the display device DD may be defined by the non-display area NDA. At least a portion of the display area DA may be surrounded by the non-display area NDA. Yet, the shape of the display area DA and the non-display area NDA is not limited to the above configuration and may be modified.

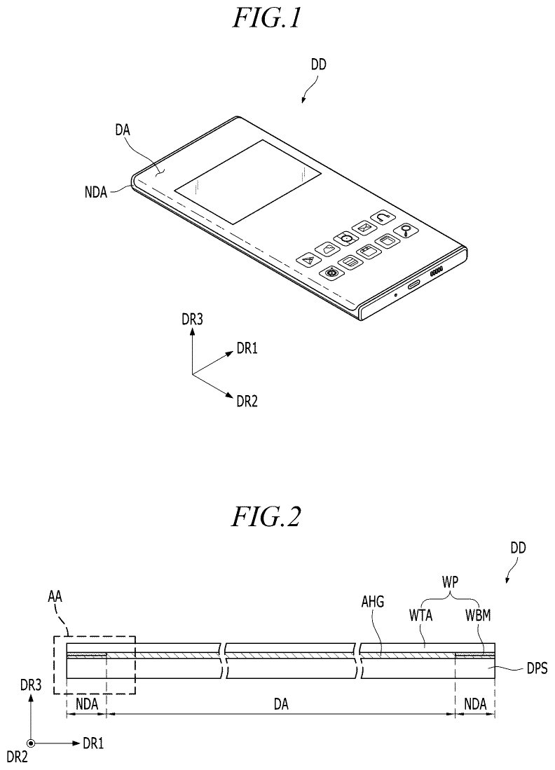

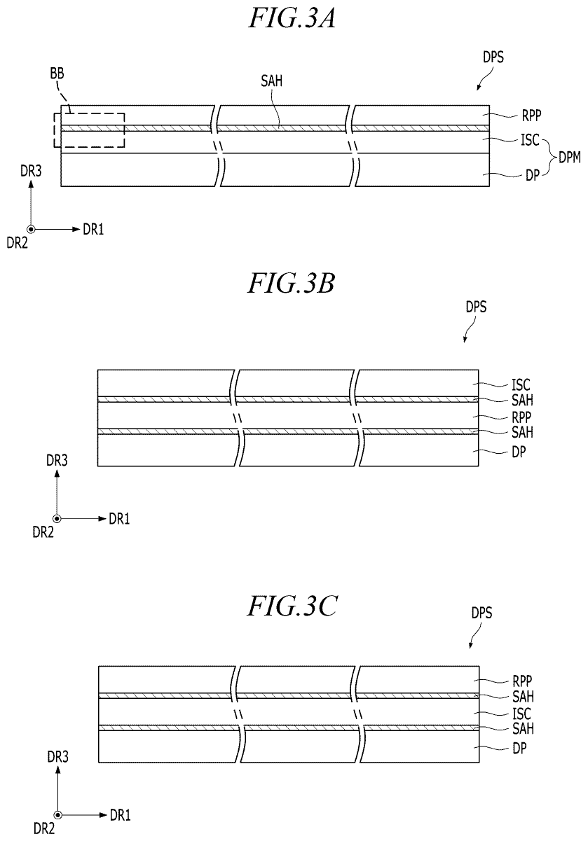

FIG. 2 is an exemplary cross-sectional view of a display device DD according to an embodiment of the present disclosure. FIG. 3A, FIG. 3B and FIG. 3C are exemplary cross-sectional views of a display substrate DPS according to an embodiment of the present disclosure. FIG. 2, FIG. 3A, FIG. 3B and FIG. 3C are illustrations of cross-sections defined by the first directional axis DR1 and the third directional axis DR3. FIG. 2, FIG. 3A, FIG. 3B and FIG. 3C may be simplified views for describing laminated relationships among functional panels and/or functional members of the display device DD and the display substrate DPS.

Referring to FIG. 2, the display device DD may include a display substrate DPS, an adhesive group AHG, and a window member WP.

The display substrate DPS may be configured to emit light. In addition, the display substrate DPS may be configured to display an image. The display substrate DPS may be defined with a display area DA and a non-display area NDA. In addition, the display substrate DPS may be formed by laminating multiple layers. For example, a display panel DP, an input sensor circuit ISC, and a reflection protection member RPP may be laminated to form a display substrate DPS.

The adhesive group AHG may be disposed on the display substrate DPS. The adhesive group AHG may attach the display substrate DPS and the window member WP together. In addition, the adhesive group AHG may be configured to transmit light. Accordingly, light emitted from the display substrate DPS may pass through the adhesive group AHG.

The window member WP may be disposed on the adhesive group AHG. The window member WP may include a light transmission part WTA and a light blocking part WBM. The light transmission part WTA may include glass and/or a synthetic resin. The light transmission part WTA is not limited to a single layer. The light transmission part WTA may include two or more films attached by an adhesive member.

The light blocking part WBM may partially overlap with the light transmission part WTA. The light blocking part WBM may be disposed below the light transmission part WTA and overlap with the non-display area NDA of the display device DD. The light blocking part WBM may be disposed on a periphery of the window member WP and may define the non-display area NDA. The adhesive group AHG may be disposed on the display substrate DPS and may facilitate a reduction in a width of the light blocking part WBM and an increase in a size of the display area DA.

Referring to FIG. 3A, the display substrate DPS may include a display module DPM, a sub adhesive part SAH and a reflection protection member RPP.

The display module DPM may include a display panel DP and an input sensor circuit ISC. In addition, the input sensor circuit ISC may be directly disposed on the display panel DP. When an element is “directly disposed on” another element, it shall be construed that there is no other adhesive layer/adhesive member interposed therebetween.

The display panel DP according to an embodiment of the present disclosure may be a light-emitting display panel. For example, a display panel DP may be an organic light-emitting display panel, a quantum dot light-emitting display panel, or a micro light-emitting display panel. Hereinafter and by way of example, not limitation, the display panel DP is described as an organic light-emitting display panel.

The input sensor circuit ISC may be disposed on the display panel DP. The input sensor circuit ISC may be configured to obtain a coordination information of an external input. More particularly, at least one of a resistance film type input sensor, a capacitance type input sensor, an optical sensor, an electromagnetic resonance type input sensor, an ultrasonic type input sensor, or an infrared wave type input sensor may be used as the input sensor circuit ISC. The sub adhesive part SAH may be disposed on the display module DPM. The sub adhesive part SAH may be configured to attach the display module DPM and the reflection protection member RPP together. In addition, the sub adhesive unit SAH may be configured to transmit light. Accordingly, light emitted from the display module DPM may pass through the sub adhesive part SAH.

The reflection protection member RPP may be disposed on the sub adhesive part SAH. The reflection protection member RPP may reduce a reflection rate of an external light incident from an upper side of the window member WP. The reflection protection member RPP according to an embodiment of the present disclosure may include a retarder, a polarizer and a plurality of color filters. Referring to FIG. 3B, a display substrate DPS may include a display panel DP, a reflection protection member RPP disposed on the display panel DP, an input sensor circuit ISC disposed on the reflection protection member RPP, and a plurality of sub adhesive parts SAH.

The display panel DP and the reflection protection member RPP may be coupled by the sub adhesive part SAH. The reflection protection member RPP and the input sensor circuit ISC may be coupled by the sub adhesive part SAH.

Referring to FIG. 3C, a display substrate DPS may include a display panel DP, an input sensor circuit ISC disposed on the display panel DP, a reflection protection member RPP disposed on the input sensor circuit ISC, and a plurality of sub adhesive parts SAH.

The display panel DP and the input sensor circuit ISC may be coupled by the sub adhesive part SAH. The input sensor circuit ISC and the reflection protection member RPP may be coupled by the sub adhesive part SAH.

A configuration of the display substrate DPS is not limited to the above descriptions. For example, the display substrate DPS may include a display area DA and a non-display area NDA defined and a window member WP attached through an adhesive group AHG. For example, a display panel DP can be a display substrate DPS. In addition, even if an input sensor circuit ISC and a reflection protection member RPP are not included, the display panel DP may be provided as a display substrate DPS. Furthermore, even when an element that is not illustrated in FIG. 3A, FIG. 3B and FIG. 3C, is further included, it can be a display substrate DPS.

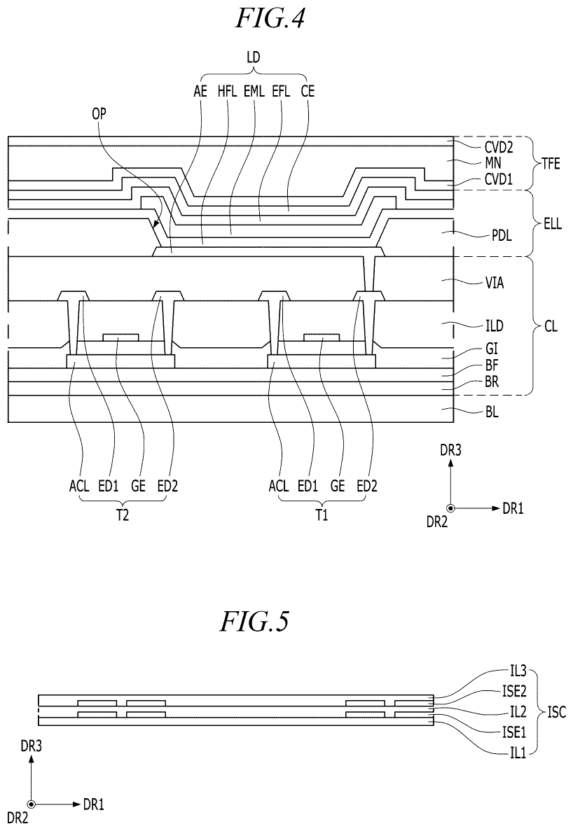

FIG. 4 is an exemplary illustration of a display panel DP according to an embodiment of the present disclosure.

Referring to FIG. 4, the display panel DP may include a base member BL, a circuit layer CL, a light-emitting diode layer ELL, and an encapsulation layer TFE.

The circuit layer CL may be disposed on the base member BL. That is, an element of the circuit layer CL may be laminated on the base member BL. The base member BL may include an organic layer and/or an inorganic layer. The organic layer may include an organic material. For example, polyimide may be included in the base member BL. The inorganic layer may include an inorganic material.

The base member BL may include a plurality of organic layers and a plurality of inorganic layers alternately laminated. Through such configuration, it may become more difficult for an impurity provided from the bottom of the display panel DP to penetrate through the base member BL. Accordingly, the circuit layer CL disposed above the base member BL may be protected by the base member BL. The circuit layer CL may include a barrier layer BR, a buffer layer BF, a gate insulating layer GI, an interlayer insulating layer ILD, a circuit insulating layer VIA and a plurality of transistors T1 and T2.

The plurality of transistors T1 and T2 may transfer an electrical signal. Furthermore, each of the plurality of transistors T1 and T2 may include an active unit ACL, a first electrode ED1, a control electrode GE, and a second electrode ED2. The barrier layer BR may be disposed on the base member BL. The barrier layer BR may be a barrier to inhibit or prevent the diffusion of metals, such as copper or aluminum, into the layers above. The barrier layer BR may improve the adhesion between the base member BL and the buffer layer BF. The barrier layer BR may be formed of, for example, tantalum (Ta), tantalum nitride (TaN), or titanium nitride (TiN). The barrier layer BR may be omitted. The buffer layer BF may be disposed on the base member BL or the barrier layer

BR. The buffer layer BF may inhibit or prevent an impurity flown from the bottom from moving above. Accordingly, an element disposed above the buffer layer BF may be protected. The plurality of active units ACL forming each transistor of the plurality of transistors T1 and T2 may be disposed on the buffer layer BF. Each active unit of the plurality of active units ACL may include a poly silicon, an amorphous silicon, or a metal oxide semiconductor. Each active unit of plurality of active units ACL may include a channel area serving as a passage through which an electron or a hole may move, and a first ion-doped area and a second ion-doped area disposed with the channel area disposed therebetween.

The gate insulating layer GI may be configured to cover the buffer layer BF and a plurality of active units ACL. The gate insulating layer GI may include an organic and/or inorganic film. The gate insulating layer GI may include a plurality of inorganic thin films. The plurality of inorganic thin films may include a silicon nitride layer and a silicon oxide layer.

The plurality of control electrodes GE of the plurality of transistors T1 and T2 may be disposed on the buffer layer BF. The plurality of control electrodes GE may overlap the plurality of active units ACL. In addition, the plurality of control electrodes GE may include molybdenum (Mo). The interlayer insulating layer ILD may be configured to cover the gate insulating layer GI and the plurality of control electrodes GE. The interlayer insulating layer ILD may include an organic film and/or an inorganic film. The interlayer insulating layer ILD may include a plurality of inorganic films or organic films. The plurality of inorganic films may include a silicon nitride layer and silicon oxide layer. The plurality of first electrodes ED1 and the plurality of second electrodes ED2 of the plurality of transistors T1 and T2 may be disposed on the interlayer insulating layer ILD. Each of the plurality of first electrodes ED1 and the plurality of second electrodes ED2 may be electrically connected to the plurality of active units ACL through the contact holes defined on the interlayer insulating layer ILD. Portions of the plurality of first electrodes ED1 and the plurality of second electrodes ED2 may be disposed on the interlayer insulating layer ILD. Furthermore, the first electrodes ED1 and the second electrodes ED2 may include a metal. In addition, the first electrodes ED1 and the second electrodes ED2 may have a multiple layer structure. More particularly, each of the first electrodes ED1 and the second electrodes ED2 may be successively laminated with titanium (Ti), aluminum (Al), and titanium (Ti). The circuit insulating layer VIA may cover the interlayer insulating layer ILD, the plurality of first electrodes ED1, and the plurality of second electrodes ED2. The circuit insulating layer VIA may include an organic film and/or an inorganic film. The circuit insulating layer VIA may provide a flat surface. A thickness of the circuit insulating layer VIA may be increased or decreased. The circuit insulating layer VIA may be provided as a number of layers.

The light-emitting diode layer ELL may include a pixel defining layer PDL and a light-emitting diode LD. The pixel defining layer PDL may be disposed on a portion of the circuit insulating layer VIA. Accordingly, the pixel defining layer PDL may define an opening part. The pixel defining layer PDL and the opening part may expose the circuit insulating layer VIA. In addition, the light-emitting diode LD may be formed on the circuit insulating layer VIA in the opening part. The light-emitting diode LD may emit light. Furthermore, the light-emitting diode LD may include an anode electrode AE, a hole functional layer HFL, a light-emitting layer EML, an electron functional layer EFL, and a cathode electrode CE. The anode electrode AE may be disposed on a portion of the circuit insulating layer VIA, particularly the opening part. Furthermore, the anode electrode AE may be electrically connected to the second electrode ED2 through the contact hole defined on the circuit insulating layer VIA. Therefore, the anode electrode AE may be configured to receive an electric signal from the first transistor T1 and the second transistor T2.

In FIG. 4, the first transistor T1 and the second transistor T2 are exemplarily illustrated, however the structures of the first transistor T1 and the second transistor T2 are not limited to what is illustrated in the figure. In FIG. 4, the first transistor T1 is illustrated to make direct contact with the anode electrode AE of the light-emitting diode LD by the second electrode ED2, but this is merely a cross-sectional shape and the first transistor T1 may be connected to the anode electrode AE of the light-emitting diode LD through another transistor. The present disclosure is not limited to this configuration, and in an embodiment of the present disclosure, the first transistor T1 may make direct contact with the anode electrode AE of the light-emitting diode LD by the second electrode ED2. The hole functional layer HFL may be disposed on the anode electrode AE. The hole functional layer HFL may support transfer of a hole generated from the anode electrode AE. For example, the hole functional layer HFL may be configured to receive a hole injected from the anode electrode AE, and the hole may be transferred therethrough. The hole functional layer HFL may have a multiple layer structure. For example, the hole functional layer HFL may have a structure of further including a hole injection layer (not shown) and a hole transfer layer (not shown). The light-emitting layer EML may be disposed on the hole functional layer HFL. The light-emitting layer EML may emit light. The light-emitting layer EML may include an organic light-emitting material or a quantum dot. Furthermore, the light-emitting diode LD may be an organic light-emitting diode or a quantum dot light-emitting diode. The electron functional layer EFL may be disposed on the light-emitting layer EML. The electron functional layer EFL may support transfer of an electron generated from the cathode electrode CE. For example, the electron functional layer EFL may receive an electron injected from the cathode electrode CE, and the electron may be transferred therethrough. The electron functional layer EFL may have a multiple layer structure. For example, the electron functional layer EFL may have a structure of further including an electron injection layer and an electron transfer layer. The cathode electrode CE may be disposed on the electron functional layer EFL. The cathode electrode CE may have low resistance so that electron current may easily flow.

The encapsulation layer TFE may be configured to seal off the light-emitting diode LD to protect the light-emitting diode LD from external oxygen or moisture. The encapsulation layer TFE may include a first encapsulation inorganic layer CVD1, an encapsulation organic layer MN, and a second encapsulation inorganic layer CVD2. In FIG. 4, the encapsulation layer TFE is illustrated, as an example, to include two encapsulation inorganic layers CVD1 and CVD2 and one encapsulation organic layer MN, but the present disclosure is not limited to this example. For example, the encapsulation layer TFE may include three encapsulation inorganic layers and two encapsulation organic layers, and in this case, the encapsulation inorganic layers and the encapsulation organic layers may be alternately laminated.

FIG. 5 is an exemplary illustration of an input sensor circuit ISC according to an embodiment of the present disclosure.

Referring to FIG. 5, the input sensor circuit ISC may include a first inorganic insulating layer IL1, a first input sensor electrode ISE1, a second inorganic insulating layer IL2, a second input sensor electrode ISE2, and a third inorganic insulating layer IL3. The input sensor circuit ISC may be configured to detect an external input to generate an input sensor signal. For example, the input sensor circuit ISC may be disposed on the encapsulation layer TFE of FIG. 4.

The first inorganic insulating layer IL1 may be disposed on the encapsulation layer TFE. The first inorganic insulating layer IL1 may have a single layer structure or a multiple layer structure. The first inorganic insulating layer IL1 may include an inorganic material or a composite material. An inorganic material may include at least one of aluminum oxide, titanium oxide, silicon oxide, silicon oxynitride, zirconium oxide, or hafnium oxide. In another embodiment, the first inorganic insulating layer IL1 may be replaced with an organic insulating layer. Furthermore, the first inorganic insulating layer IL1 may be omitted.

The first input sensor electrode ISE1 may be disposed on the first inorganic insulating layer IL1. The first input sensor electrode ISE1 may have a single layer structure or a laminated multiple layer structure. The electrode of a single layer structure may include a metal layer or a transparent electrode. The metal layer may include at least one of a molybdenum, silver, titanium, copper, or aluminum, or an alloy thereof. The transparent electrode may include a transparent conductive oxide, such as indium tin oxide (ITO), indium zinc oxide (IZO), zinc oxide (ZnO), or indium tin zinc oxide (ITZO). Another transparent electrode may include a conductive polymer, such as PEDOT, a metallic nanowire or graphene. Furthermore, the multiple layer structure may be successively laminated with titanium (Ti), aluminum (Al), and titanium (Ti).

The second inorganic insulating layer IL2 may be disposed on the first input sensor electrode ISE1. The specific configuration of the second inorganic insulating layer IL2 may be the same as that of the first inorganic insulating layer IL1.

The second input sensor electrode ISE2 may be disposed on the second inorganic insulating layer IL2. The specific configuration of the second input sensor electrode ISE2 may be the same as that of the first input sensor electrode ISE1.

Meanwhile, a capacitor may be formed between the first input sensor electrode ISE1 and the second input sensor electrode ISE2. Furthermore, the capacitor may be affected by an external input. A change in a microcurrent may be caused by the capacitor to generate an electron sensor signal so that a coordinate information may be obtained through the input sensor signal.

The third insulating layer IL3 may be disposed on the second input sensor electrode ISE2. The specific configuration of the third inorganic insulating layer IL3 may be the same as that of the first inorganic insulating layer IL1.

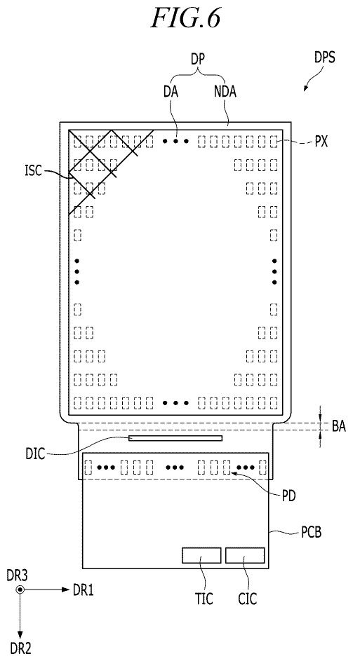

FIG. 6 is an exemplary plan view of a display substrate DPS according to an embodiment of the present disclosure.

Referring to FIG. 6, the display substrate DPS may include a display panel DP, an input sensor circuit ISC, a circuit substrate PCB, an input sensor driving unit TIC, and a control driving unit CIC. The display panel DP may include a plurality of pixels PX, a data driving unit DIC, and a plurality of pads PD. Meanwhile, a reflection protection member RPP and a sub adhesive part SAH are omitted in FIG. 6.

The display panel DP may be defined with a display area DA and a non-display area NDA. More particularly, an area surrounding the display area DA may be defined as the non-display area NDA. Furthermore, a light-emitting diode LD included in the display panel DP may overlap with the display area DA. The display area DA and the non-display area NDA of the display panel DP may respectively correspond to the display area DA and the non-display area NDA of the display device DD shown in FIG. 1 and FIG. 2.

The input sensor circuit ISC may be disposed on the display area DA. The input sensor circuit ISC may be configured to generate an input sensor signal from an external input.

An input sensor driving unit TIC and a control driving unit CIC may be disposed on the circuit substrate PCB.

The input sensor driving unit TIC may be mounted on the circuit substrate PCB and configured to receive an input sensor signal. Furthermore, the input sensor driving unit TIC may be configured to process the input sensor signal.

The control driving unit CIC may be mounted on the circuit substrate PCB and configured to transmit and/or receive a signal. Furthermore, the control driving unit CIC may be a circuit configured to control at least one of the data driving unit DIC or the input sensor driving unit TIC.

The plurality of pixels PX may be disposed in the display area DA. Furthermore, the plurality of pixels PX may be configured to receive power and an electric signal, and to emit light. The light emitted by the plurality of pixels PX by the electric signal may form an image displayed in the display area DA.

The data driving unit DIC may be electrically connected to the plurality of pixels PX in the display area DA to provide a data signal to the plurality of pixels PX.

The plurality of pads PD may make contact with and be electronically connected to the circuit substrate PCB. Accordingly, the display module DPM and the circuit substrate PCB may be configured to exchange an electrical signal and power through the plurality of pads PD.

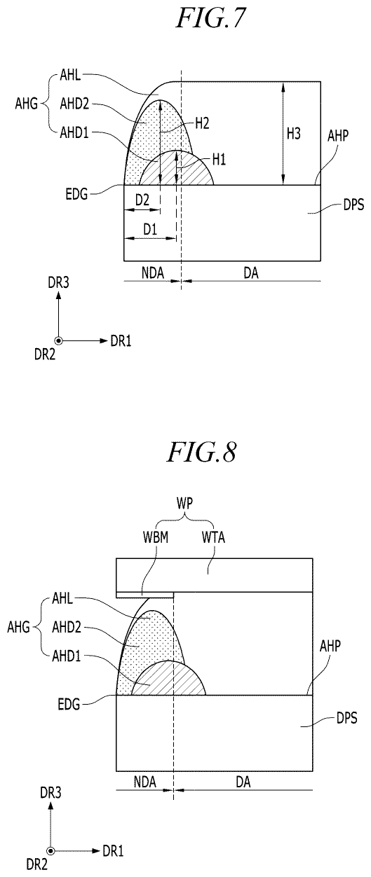

FIG. 7 is an exemplary magnified view of a portion marked with AA shown in FIG. 2 by omitting a window member WP.

Referring to FIG. 7, the display substrate DPS of the present disclosure may be defined with an adhesive surface AHP and an edge part EDG. In addition, an adhesive group AHG may be disposed on the adhesive surface AHP. The adhesive group AHG may include a plurality of adhesive elements. The adhesive group AHG may include a first adhesive dam AHD1, a second adhesive dam AHD2, and an adhesive layer AHL.

The adhesive surface AHP may be defined as a surface that is most distant from the base member BL among a plurality of surfaces composing the display substrate DPS. Otherwise, the adhesive surface AHP may be defined as a surface where the adhesive group AHG may be attached among a plurality of surfaces forming the display substrate DPS.

The adhesive surface AHP may be a side of the reflection protection member RPP. Otherwise, the adhesive surface AHP may be a side of the input sensor circuit ISC. For example, the adhesive surface AHP may be a side of the third inorganic insulating layer IL3. Otherwise, the adhesive surface AHP may be a side of the display panel. For example, the adhesive surface AHP may be a side of the second encapsulation inorganic layer CVD2. Meanwhile, a configuration of the adhesive surface AHP is not limited thereto. The adhesive surface AHP may be a side of another element included in the display substrate DPS.

The edge part EDG may be defined as a plurality of edges making contact with the adhesive surface AHP among a plurality of edges composing the display substrate DPS. The edge part EDG may extend from a periphery of the adhesive surface AHP and may form a plurality of edges composing the display substrate DPS. The edge part EDG may be a plurality of sides of the adhesive surface AHP.

The adhesive group AHG may be attached to the window member WP. As a result, the display substrate DPS and the window member WP may be attached with the adhesive group AHG therebetween. In addition, an inclined surface may be formed by an outer surface of the adhesive group AHG.

The first adhesive dam AHD1 may be disposed on the adhesive surface AHP. The first adhesive dam AHD1 may be directly disposed on the adhesive surface AHP. In addition, the first adhesive dam AHD1 may have at least a portion overlapping with the non-display area NDA. The first adhesive dam AHD1 may have at least a portion overlapping with the display area DA. The first adhesive dam AHD1 may exposed at least a portion overlapping with the non-display area NDA.

The first adhesive dam AHD1 may be formed in a shape of a dam. More particularly, the first adhesive dam AHD1 may be formed in a shape of extending in the second direction DR2 in the figure. In addition, the first adhesive dam AHD1 may have a height of a first height H1. Furthermore, a distance between a foot of a perpendicular line from a first height H1 point of the first adhesive dam AHD1 to the adhesive surface AHP and the edge part EDG may be a first distance D1.

An optically clear resin may be disposed to form the first adhesive dam AHD1. More particularly, the first adhesive dam AHD1 may include a photocurable material. The photocurable material may include an acrylate-based molecule. For example, the photocurable material may include a monomer of at least one of an alkyl acrylate monomer, an alkyl metacrylate monomer, or an urethane acrylate monomer. In addition, the photocurable material may further include a polymerization initiator. Furthermore, the photocurable material may be cured to form an acrylate-based copolymer.

In addition, the optically clear resin has low viscosity so that it can be sprayed. More particularly, a viscosity of the optically clear resin may be between about 5 cP (centipoise) and about 40 cP at a room temperature. For example, a viscosity of the optically clear resin may be about 12 cP at a room temperature. Accordingly, the optically clear resin may be sprayed. In addition, the first adhesive dam AHD1 may be disposed as the optically clear resin is sprayed. As used herein, “about” means within 10%, or more particularly, within 5% of the stated value unless otherwise specified, or may include expected variations (e.g., manufacturing variabilities).

In addition, the first adhesive dam AHD1 may be affected by a surface tension of the first adhesive dam AHD1 and surface energy of the first adhesive dam AHD1, the adhesive surface AHP and an interface between the first adhesive dam AHD1 and the adhesive surface AHP. More particularly, a shape of the first adhesive dam AHD1 may be affected by the surface tension and the surface energy.

For example, a surface tension of an optically clear resin forming the first adhesive dam AHD1 may be about 30.2 mN/m. In addition, surface energy of the optically clear resin may be about 32.6 mJ/m².

In addition, a contact angle of the first adhesive dam AHD1 disposed on the adhesive surface AHP may be affected by the surface tension and the surface energy. More particularly, a contact angle of the first adhesive dam AHD1 disposed on the adhesive surface AHP may be defined as a first contact angle. The adhesive surface AHP that is in contact with the first adhesive dam AHD1 may be flat. In addition, the first contact angle may be, for example, about 21 degrees. Meanwhile, the first contact angle of the first adhesive dam AHD1 disposed on the adhesive surface AHP may be modified according to a shape of the adhesive surface AHP.

In addition, light may be irradiated on the first adhesive dam AHD1 so that the first adhesive dam AHD1 can be cured. More particularly, radioactive waves may be irradiated on the first adhesive dam AHD1. Meanwhile, after the first adhesive dam AHD1 is disposed, the first adhesive dam AHD1 may be pre-cured. That is, in a pre-curing a small amount of light may be irradiated to the first adhesive dam AHD1. The small amount of light irradiated during the pre-cure may be less than an amount of light irradiated during a main curing, which will be described below. In addition, a degree of cure of the first adhesive dam AHD1 may be defined as a first degree of cure.

A degree of cure may be a scale that shows a degree of hardening of a plurality of photocurable molecules. The degree of cure may be measured by a distribution of bonds of the plurality of photocurable molecules. The curing of a photocurable molecules may involve a photochemical reaction that converts an adhesive into a cured polymer by breaking and re-forming chemical bonds, which may be double bonds (e.g., C═C) in the adhesive's molecular structure. This process may be initiated by light. For example, when the plurality of photocurable molecules have relatively more double bonds, a degree of cure may be low, and when the plurality of photocurable molecules have relatively fewer double bonds, a degree of cure may be high.

A degree of cure may be measured by a UV degree of cure measurement method. More particularly, a degree of cure may be measured by analyzing fluorescence emitted from a specimen after radioactive waves have been irradiated on the specimen. Furthermore, a degree of cure may be measured through a DSC analysis. A degree of cure may be measured by analyzing a glass transition temperature of a specimen after the specimen is heated. In addition, a degree of cure may be measured by analyzing a curing enthalpy of a specimen after the specimen is heated. The curing enthalpy may refer to the heat released (or absorbed) during the curing process of the specimen, wherein curing may involve a chemical reaction where double bonds are broken and new single bonds are formed. However, a measurement method of a degree of cure as above is merely an example, and the degree of cure may be measured through another method.

In addition, the first adhesive dam AHD1 may include a pressure sensitive adhesive. For example, a cured optically clear resin may be a pressure sensitive adhesive. Accordingly, another adhesive substrate may be attached on the first adhesive dam AHD1.

The second adhesive dam AHD2 may be disposed on the adhesive surface AHP. The second adhesive dam AHD2 may have at least a portion overlapping with the non-display area NDA. The second adhesive dam AHD2 may overlap an entirety of the non-display area NDA. The second adhesive dam AHD2 may cover a portion of the first adhesive dam AHD1. The portion of the first adhesive dam AHD1 covered by the second adhesive dam AHD2 may be a first portion of the first adhesive dam AHD1.

In addition, the second adhesive dam AHD2 may be disposed on an outer side than the first adhesive dam AHD1. In addition, a portion of the first adhesive dam AHD1 may not be covered by the second adhesive dam AHD2. The portion of the first adhesive dam AHD1 not covered by the second adhesive dam AHD2 may be a second portion of the first adhesive dam AHD1. The second adhesive dam AHD2 may expose a second portion of the first adhesive dam AHD1. For example, the second adhesive dam AHD2 may cover only an area near outside of the first adhesive dam AHD1 and may not cover the rest. The second adhesive dam AHD2 may cover an outer surface of the first adhesive dam AHD1 facing away from the display area DA, and may expose at least a portion of an inner surface of the first adhesive dam AHD1 facing toward the display area DA. Furthermore, the second adhesive dam AHD2 may have at least a portion positioned adjacent to the edge part EDG.

The second adhesive dam AHD2 may have a shape of a dam. More particularly, the second adhesive dam AHD2 may have a shape of extending in the second direction DR2 in the figure. In addition, a height of the second adhesive dam AHD2 may be a second height H2. In addition, a distance between a foot of a perpendicular line from a second height H2 point of the second adhesive dam AHD2 to the adhesive surface AHP and the edge part EDG may be a first distance D1. In addition, the second height H2 may be greater than the first height H1. In addition, the second distance D2 may be less than the first distance D1. That is, the second adhesive dam AHD2 may be disposed on an outer side than the first adhesive dam AHD1. In addition, an inclination degree of a surface of the second adhesive dam AHD2 may be greater than an inclination degree of a surface of the first adhesive dam AHD1.

An optically clear resin may be disposed to form the second adhesive dam AHD2. The optically clear resin forming the second adhesive dam AHD2 may be the same as or similar to the optically clear resin forming the first adhesive dam AHD1. Furthermore, a process of disposing the second adhesive dam AHD2 may be the same as or similar to the process of disposing the first adhesive dam AHD1.

In addition, the second adhesive dam AHD2 may be affected by a surface tension of the second adhesive dam AHD2 and surface energy of the first adhesive dam AHD1, the adhesive surface AHP, an interface between the second adhesive dam AHD2 and the first adhesive dam AHD1 and an interface between the second adhesive dam AHD2 and the adhesive surface AHP. More particularly, a shape of the second adhesive dam AHD2 may be affected by the surface tension and the surface energy.

For example, a surface tension of the optically clear resin forming the second adhesive dam AHD2 may be about 30.2 mN/m. In addition, surface energy of the optically clear resin may be about 32.6 mJ/m².

In addition, a contact angle of the second adhesive dam AHD2 disposed on the first adhesive dam AHD1 may be affected by the surface tension and the surface energy. More particularly, a contact angle of the second adhesive dam AHD2 disposed on the first adhesive dam AHD1 may be defined as a second contact angle. The first adhesive dam AHD1 that is in contact with the second adhesive dam AHD2 may be flat. In addition, the second contact angle may be greater than the first contact angle. The second contact angle may be, for example, about 50 degrees. Meanwhile, the second contact angle of the second adhesive dam AHD2 disposed on the first adhesive dam AHD1 may be modified according to a shape of the first adhesive dam AHD1.

Furthermore, light may be irradiated on the second adhesive dam AHD2 so that the second adhesive dam AHD2 is cured. More particularly, radioactive waves may be irradiated on the second adhesive dam AHD2. In addition, the second adhesive dam AHD2 may be pre-cured after the second adhesive dam AHD2 is disposed. Furthermore, a degree of cure of the second adhesive dam AHD2 may be defined as a second degree of cure.

Meanwhile, while the second adhesive dam AHD2 is cured, the first adhesive dam AHD1 may be further cured. Accordingly, the first degree of cure may be greater than the second degree of cure.

In addition, the second adhesive dam AHD2 may include a pressure sensitive adhesive. For example, a cured optically clear resin may be a pressure sensitive adhesive. Accordingly, another adhesive substrate may be attached on the second adhesive dam AHD2

The adhesive layer AHL may be disposed on the adhesive surface AHP. The adhesive layer AHL may overlap with the display area DA. Furthermore, the adhesive layer AHL may be disposed to cover the display area DA. In addition, a portion of the adhesive layer AHL may overlap with the non-display area NDA. Furthermore, the adhesive layer AHL may cover a portion of the first adhesive dam AHD1 and a portion of the second adhesive dam AHD2. In an embodiment, the first adhesive dam AHD1 may, for example, facilitate application on a display panel of various shapes and an application on a large-area display panel in comparison to the optically clear adhesive and the second adhesive dam AHD2 may, for example, has a stable shape, which may resist being movement to the outside of the display panel.

The adhesive layer AHL may be formed in a single layer shape. More particularly, a thickness of the adhesive layer AHL may be defined as a third height H3. In addition, a thickness of the adhesive layer AHL may be the same as a thickness of the adhesive group AHG in the display area DA.

Furthermore, the third height H3 may be equal to greater than the first height H1. In addition, the third height H3 may be equal to or greater than the second height H2. More particularly, the first height H1 may be between about 0.2 times and about 0.4 times the third height H3. In addition, the second height H2 may be between about 0.8 times and 1.0 times the third height H3.

An optically clear resin may be disposed to form the adhesive layer AHL. The optically clear resin forming the adhesive layer AHL may be the same as or similar to the optically clear resin forming the first adhesive dam AHD1 and the second adhesive dam AHD2. In addition, the process of disposing the adhesive layer AHL may be the same as or similar to the process of disposing the second adhesive dam AHD2 and the first adhesive dam AHD1.

In addition, the adhesive layer AHL may be affected by a surface tension of the adhesive layer AHL and surface energy of the second adhesive dam AHD2 and an interface between the adhesive layer AHL and the second adhesive dam AHD2. More particularly, a shape of the adhesive layer AHL may be affected by the surface tension and the surface energy.

For example, a surface tension of the optically clear resin forming the adhesive layer AHL may be about 30.2 mN/m. In addition, surface energy of the optically clear resin may be about 32.6 mJ/m².

In addition, a contact angle of the adhesive layer AHL disposed on the second adhesive dam AHD2 may be affected by the surface tension and the surface energy. More particularly, a contact angle of the adhesive layer AHL disposed on the second adhesive dam AHD2 may be defined as a third contact angle. The second adhesive dam AHD2 that is in contact with the adhesive layer AHL may be flat. In addition, the third contact angle may be greater than the first contact angle. The third contact angle may be, for example, about 50 degrees. Meanwhile, a substantial contact angle of the adhesive layer AHL disposed on the second adhesive dam AHD2 may be modified according to a shape of the second adhesive dam AHD2.

Furthermore, light may be irradiated on the adhesive layer AHL to cure the adhesive layer AHL. More particularly, radioactive waves may be irradiated on the adhesive layer AHL. In addition, a main curing of the adhesive layer AHL may be performed after the adhesive layer AHL is disposed. That is, in comparison to pre-curing described herein, additional light may be irradiated on the adhesive layer AHL. In addition, a degree of cure of the adhesive layer AHL may be defined as a third degree of cure.

Meanwhile, while the adhesive layer AHL is cured, the first adhesive dam AHD1 and the second adhesive dam AHD2 may be further cured. Accordingly, the first degree of cure and the second degree of cure may be greater than the third degree of cure.

In addition, a degree of cure of a portion of the adhesive layer AHL overlapping with the display area DA may be substantially the same as a degree of cure of a portion overlapping with the non-display area NDA.

Meanwhile, the first degree of cure, the second degree of cure and the third degree of cure may be about 90% or more after the main curing. More particularly, the first degree of cure may be between about 95% and about 99%. In addition, the second degree of cure may be between about 93% and about 94%. In addition, the third degree of cure may be between about 91% and about 92%.

In addition, the adhesive layer AHL may include a pressure sensitive adhesive. For example, the cured optically clear resin may be a pressure sensitive adhesive. Accordingly, another substrate may be attached on the adhesive layer AHL.

If the adhesive group AHG includes all of the first adhesive dam AHD1, the second adhesive dam AHD2 and the adhesive layer AHL, an inclination degree of the inclined surface formed outside of the adhesive group AHG may be greater. More particularly, the second adhesive dam AHD2 may be disposed to cover a portion of the first adhesive dam AHD1 after the first adhesive dam AHD1 is disposed. Therefore, the second adhesive dam AHD2 may be positioned on a curved surface formed by the first adhesive dam AHD1. In addition, the second adhesive dam AHD2 may make direct contact with the first adhesive dam AHD1.

Therefore, the second adhesive dam AHD2 may be affected by surface energy of the curved surface and between the second adhesive dam AHD2 and the first adhesive dam AHD1. As a result, the second adhesive dam AHD2 may have a different shape from the first adhesive dam AHD1. For example, as the first contact angle is greater than the second contact angle, an aspect ratio of a cross-section of the second adhesive dam AHD2 may be greater than an aspect ratio of a cross-section of the first adhesive dam AHD1. For a more specific explanation, a length of the second adhesive dam AHD2 in the third direction DR3 divided by its length in the first direction DR1 may be greater than a length of the first adhesive dam AHD1 in the third direction DR3 divided by a its length in the first direction DR1. That is, a height divided by a thickness of the second adhesive dam AHD2 may be greater than a height divided by a thickness of the first adhesive dam AHD1.

In addition, as an aspect ratio of a cross-section of the second adhesive dam AHD2 may be large, both sides of the second adhesive dam AHD2 may be formed with an inclined surface with a large inclination degree. In addition, the adhesive layer AHL may be disposed to cover an inclined surface of one side of the two inclined surfaces formed on both sides of the second adhesive dam AHD2. The adhesive layer AHL may be disposed to cover an inclined surface of an inside surface, facing the display area DA, of the inclined surfaces of the second adhesive dam AHD2. As a result, an inclination degree of an inclined surface formed outside of the adhesive group AHG may be large due to an inclined surface with a large inclination degree formed on another side of the second adhesive dam AHD2. Meanwhile, an effect by the inclination degree of the inclined surface formed outside of the adhesive group AHG is specifically described with reference to the figure described below.

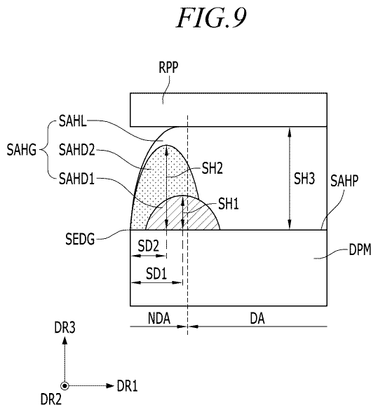

FIG. 8 is an exemplary magnified view of a portion marked with AA shown in FIG. 2.

Referring to FIG. 8, a window member WP may be disposed on the adhesive group AHG of the present disclosure. In addition, the window member WP may include a light penetrating part WTA and a light blocking part WBM.

The adhesive group AHG may be interposed between the display substrate DPS and the window member WP. In addition, the adhesive group AHG may be configured to attach the display substrate DPS and the window member WP.

Because the inclination degree of the inclined surface formed by the adhesive group AHG, a greater area may make contact with the window member WP. In addition, a display area DA may be set on an area where the adhesive group AHG and the window member WP make contact. That is, when the inclination degree of the inclined surface formed by the adhesive group AHG is large, a larger area of the display area DA may be set and the non-display area NDA may become narrower.

In the present disclosure, an area where the adhesive group AHG and the window member WP do not make contact may be narrow. Accordingly, an effect due to a size and a shape of the light-blocking part WBM may be reduced. More particularly, because an area where the adhesive group AHG and the window member WP make contact may be narrow, an area of the light-blocking part WBM may also become narrow. As a result, light may be more normally provided to the outside in the present disclosure. Specifically, light emitted from near a periphery of the display substrate DPS may be more normally provided to the outside. For example, edge artifacts, such as distortions of light that may be due to a change in refraction of light that may be due to the light-blocking part WBM may be reduced. Further, an angle of the light from the display area DA to a periphery of the light transmission part WTA may be relatively uniform in a case that a degree of inclination of the inclined surfaces of the adhesive group AHG may be large.

Meanwhile, when the adhesive group AHG does not include a first adhesive dam AHD1 and/or a second adhesive dam AHD2, the inclination degree of the inclined surface formed by the adhesive group AHG may become small. Accordingly, when the adhesive group AHG does not include a first adhesive dam AHD1 and/or a second adhesive dam AHD2, the display area DA may become narrow and light emitted from near an edge portion of the display substrate DPS may be distorted as the light is provided to the outside.

In addition, the adhesive group AHG positioned on the display area DA may have a contact height of the third height H3. Therefore, the adhesive group AHG may more stably attach the display substrate DPS and the window member WP. Accordingly, there may be no empty space interposed between the adhesive group AHG and the window member WP. For example, the formation of voids interposed between the adhesive group AHG and the window member WP may be inhibited or prevented. As a result, distortions caused by an empty space interposed between the adhesive group AHG and the window member WP may be reduced or eliminated.

In addition, the adhesive group AHG may include a pressure sensitive adhesive. Accordingly, an additional process, such as a separate light curing after attachment of the window member WP on the adhesive group AHG, may be omitted. In addition, the pressure sensitive adhesive included in the adhesive group AHG may be elastic. Therefore, even when the adhesive group AHG or the window member WP is curved, the adhesive group AHG and the window member WP may be closely attached.

FIG. 9 is an exemplary magnified view of a portion marked with BB shown in FIG. 3A.

Referring to FIG. 3A and FIG. 9, the sub adhesive part SAH shown in FIG. 3A may have the same shape as the sub adhesive group SAHG shown in FIG. 9. In addition, the display module DPM of the present disclosure may be defined with a sub adhesive surface SAHP and a sub edge part SEDG. Furthermore, the sub adhesive group SAHG may be disposed on the sub adhesive surface SAHP. The sub adhesive group SAHG may include a first sub adhesive dam SAHD1, a second sub adhesive dam SAHD2 and a sub adhesive layer SAHL.

The sub adhesive surface SAHP may be defined as a surface that is most distant from the base member BL among a plurality of surfaces composing the display module DPM. Meanwhile, the sub adhesive surface SAHP may be defined as a surface where the sub adhesive group SAHG is attached among a plurality of surfaces composing the display module DPM.

The sub edge part SEDG may be defined as a plurality of edges adjacent to the sub adhesive surface SAHP among a plurality of edges composing the display module DPM.

The sub adhesive group SAHG may be attached to the reflection protection member RPP. The sub adhesive group SAHG may merely have different adjacent substrates from the adhesive group AHG and have the same structure as the adhesive group AHG. More particularly, the first sub adhesive dam SAHD1 may have the same structure as the first adhesive dam AHD1, the second sub adhesive dam SAHD2 may have the same structure as the second adhesive dam AHD2, and the sub adhesive layer SAHL may have the same structure as the adhesive layer AHL.

A height of the first sub adhesive dam SAHD1 may be a first sub height SH1. In addition, a distance between a foot of a perpendicular line from a first sub height SH1 point of the first sub adhesive dam SAHD1 to a sub adhesive surface SAHP and a sub edge part SEDG may be a first sub distance SD1.

A height of the second sub adhesive dam SAHD2 may be a second sub height SH2. In addition, a distance between a foot of a perpendicular line from a second sub height SH2 point of the second sub adhesive dam SAHD2 to a sub adhesive surface SAHP and the sub edge part SEDG may be a second sub distance SD2.

A thickness of the sub adhesive layer SAHL may be defined as a third sub height SH3. In addition, a thickness of the sub adhesive layer SAHL may be the same as a thickness of the sub adhesive group SAHG in the display area DA.

A relationship among the first sub height SH1, the second sub height SH2 and the third sub height SH3 may correlate to a relationship among the first height H1, the second height H2 and the third height H3. In the relationship among the first height H1, the second height H2 and the third height H3, the first height H1 is replaced by the first sub height SH1, the second height is replaced by the second sub height SH2, and the third height H3 is replaced by the third sub height SH3 to explain the relationship among the first sub height SH1, the second sub height SH2 and the third sub height SH3.

In addition, a relationship between the first sub distance SD1 and the second sub distance SD2 may correlate to a relationship between the first distance D1 and the second distance D2. In the relationship between the first distance D1 and the second distance D2, the first distance D1 may be replaced by the first sub distance SD1 and the second distance may be replaced by the second sub distance SD2 to explain the relationship among the first sub distance SD1 and the second sub distance SD2.

When the sub adhesive group SAHG may include all of the first sub adhesive dam SAHD1, the second sub adhesive dam ASHD2 and the sub adhesive layer SAHL, an inclination degree of an inclined surface formed outside of the sub adhesive group SAHG may be large. Accordingly, an area of the display area DA may be increased and the non-display area NDA may become narrower. In addition, light emitted from near a periphery of the display module DPM may be more normally provided to the outside. For example, the sub adhesive group SAHG may be disposed on the display module DPM and may have a structure that facilitates a reduction in a width of the non-display area NDA, and an increase in a size of the display area DA.

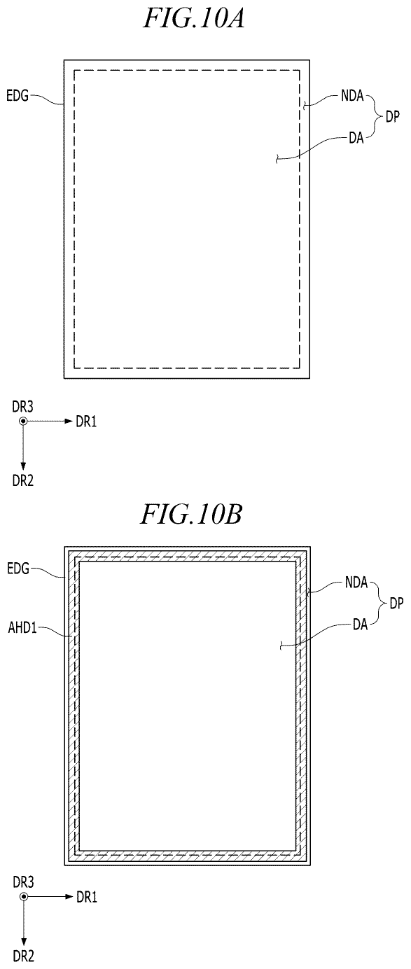

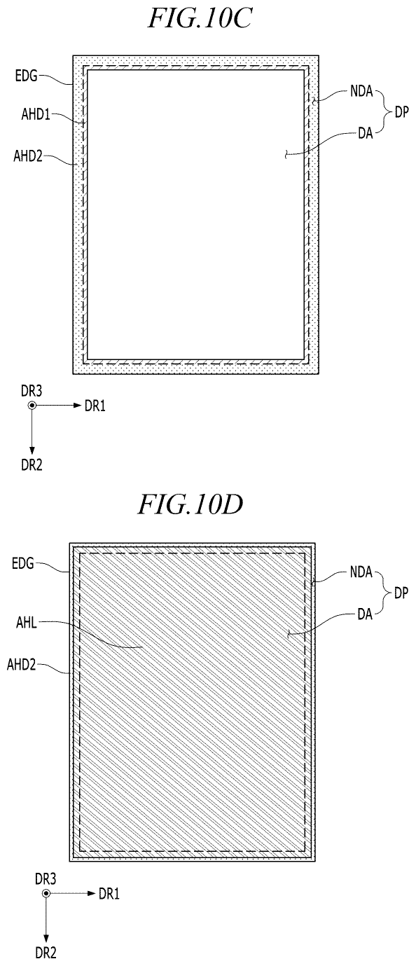

FIGS. 10A through 10D are exemplary illustrations of a process of forming an adhesive group AHG on an adhesive surface AHP according to an embodiment of the present disclosure.

Referring to FIG. 10A, the adhesive surface AHP may overlap with the display area DA and the non-display area NDA. The adhesive surface AHP is illustrated as a rectangle in FIG. 10A, but an embodiment of the present disclosure is not limited to the shape of the adhesive surface AHP shown in FIG. 10A.

Referring to FIG. 10B, the first adhesive dam AHD1 may be disposed on the adhesive surface AHP. In addition, the first adhesive dam AHD1 may have at least a portion overlapping with the non-display area NDA. The first adhesive dam AHD1 may extend along a boundary portion between the display area DA and the non-display area NDA. As described herein, even when the shape of the adhesive surface AHP is not a rectangle, the first adhesive dam AHD1 may extend along a boundary portion between the display area DA and the non-display area NDA.

Referring to FIG. 10C, the second adhesive dam AHD2 may be disposed on the adhesive surface AHP. In addition, the second adhesive dam AHD2 may have at least a portion overlapping with the non-display area NDA. The second adhesive dam AHD2 may extend along the first adhesive dam AHD1. In addition, the second adhesive dam AHD2 may have at least a portion disposed adjacent to the edge part EDG. As described herein, even when the shape of the adhesive surface AHP is not a rectangle, the second adhesive dam AHD2 may extend along the first adhesive dam AHD1.

Referring to FIG. 10D, the adhesive layer AHL may be disposed on the adhesive surface AHP. In addition, the adhesive layer AHL may be disposed to cover the display area DA. The adhesive layer AHL may have at least a portion overlapping with the first adhesive dam AHD1 and the second adhesive dam AHD2. In addition, the adhesive layer AHL may have at least a portion surrounded by the first adhesive dam AHD1 and the second adhesive dam AHD2.

Hereinafter, another embodiment of the present disclosure is more specifically explained with reference to a figure.

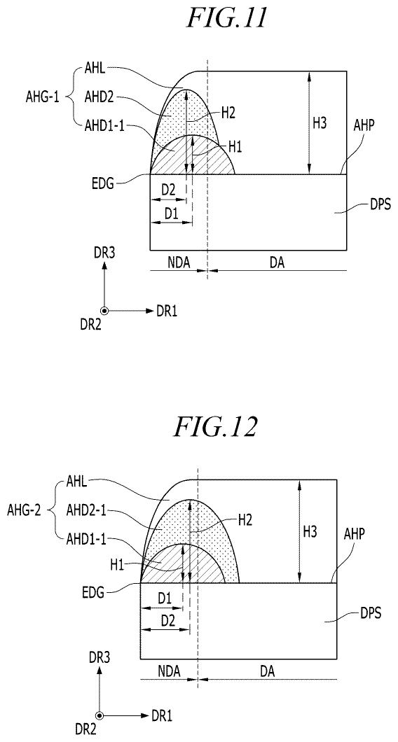

FIG. 11 is an exemplary magnified view of a portion marked with AA shown in FIG. 2 by omitting a window member WP. Referring to FIG. 11, at least a portion of the first adhesive dam AHD1-1 may be disposed adjacent to the edge part EDG. In addition, the entire second adhesive dam AHD2 may overlap with the first adhesive dam AHD1.

In FIG. 11, the first adhesive dam AHD1-1 and the second adhesive dam AHD2 may be disposed adjacent to the edge part EDG. Therefore, the second adhesive dam AHD2 may be positioned on an inclined surface formed by the first adhesive dam AHD1-1. That is, an inclined surface formed by the second adhesive dam AHD2 may overlap with the inclined surface formed by the first adhesive dam AHD1-1.

Therefore, an inclination degree of an inclined surface formed outside of the adhesive group AHG-1 may be large. Accordingly, a larger area of the display area DA may be set, and the non-display area NDA may become narrow. Furthermore, light emitted from near a periphery of the display substrate DPS may be more normally provided to the outside.

As a result, even when the first adhesive dam AHD1-1 has at least a portion positioned adjacent to the edge part EDG, the adhesive group AHG-1 may facilitate an increase in an area of the display area DA and narrow non-display area NDA. In addition, light emitted from near a periphery of the display module DPM may be more normally provided to the outside.

FIG. 12 is an exemplary magnified view of a portion marked with AA shown in FIG. 2 by omitting a window member WP.

Referring to FIG. 12, the first adhesive dam AHD1-1 may have at least a portion positioned adjacent to the edge part EDG. In addition, the second adhesive dam AHD2-1 may cover the entire first adhesive dam AHD1-1. Furthermore, the first distance D1 may be greater than the second distance D2.

In FIG. 12, the first adhesive dam AHD1-1 and the second adhesive dam AHD2-1 may be positioned adjacent to the edge part EDG. Therefore, the second adhesive dam AHD2-1 positioned adjacent to the edge part EDG may be positioned on an inclined surface formed by the first adhesive dam AHD1-1. That is, an inclined surface formed by the second adhesive dam AHD2-1 may overlap with the inclined surface formed by the first adhesive dam AHD1-1.

Therefore, an inclination degree of an inclined surface formed outside of the adhesive group AHG-2 may be large. Accordingly, a larger area of the display area DA may be set and the non-display area NDA may become narrower. In addition, light emitted from near a periphery of the display substrate DPS may be more normally provided to the outside.

As a result, even when the first distance D1 is greater than the second distance D2, the adhesive group AHG-2 may facilitate an increase in an area of the display area DA and narrow non-display area NDA. In addition, light emitted from near a periphery of the display module DPM may be more normally provided to the outside.

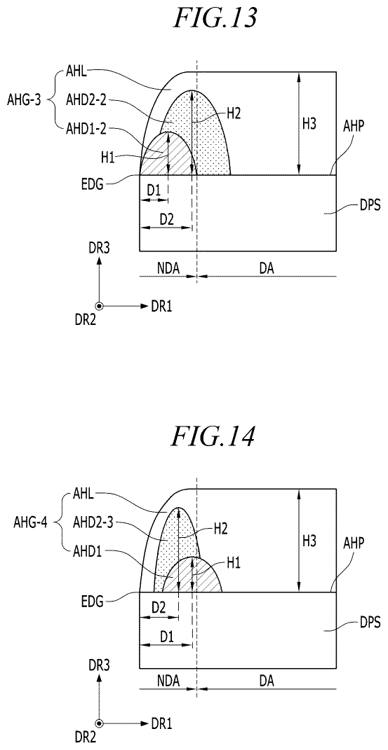

FIG. 13 is an exemplary magnified view of a portion marked with AA shown in FIG. 2 by omitting a window member WP. Referring to FIG. 13, the first adhesive dam AHD1-2 may have at least a portion positioned adjacent to the edge part EDG. In addition, the second adhesive dam AHD2-2 may not be positioned adjacent to the edge part EDG. Furthermore, the second distance D2 may be greater than the first distance D1.

In FIG. 13, the first adhesive dam AHD1-2 may be positioned adjacent to the edge part EDG. Accordingly, when the second adhesive dam AHD2-2 and the adhesive layer AHL are disposed on the first adhesive dam AHD1-2, an inclination degree of an inclined surface formed outside of the adhesive group AHG-3 may be large.

In addition, the second adhesive dam AHD2-2 may be detachedly disposed from the edge part EDG in FIG. 13. Furthermore, the second adhesive dam AHD2-2 may interrupt flow of the adhesive layer AHL before curing. Therefore, the inclination degree of the inclined surface formed outside of the adhesive group AHG-3 may be large.

Accordingly, for a window member WP of a given size, an area of the display area DA may be increased, and the non-display area NDA may become narrower. In addition, light emitted from near a periphery of the display substrate DPS may be more normally provided to the outside.

As a result, even when the second adhesive dam AHD2-2 is not positioned adjacent to the edge part EDG, the adhesive group AHG-3 may facilitate an increase in an area of the display area DA and narrow non-display area NDA. In addition, light emitted from near a periphery of the display module DPM may be more normally provided to the outside. For example, distortion of the light emitted near a periphery of the display module DPM may be reduced, allowing the light to be provided normally to the outside.

FIG. 14 is an exemplary magnified view of a portion marked with AA shown in FIG. 2 by omitting a window member WP. Referring to FIG. 14, the first adhesive dam AHD1 and the second adhesive dam AHD2-3 may not be positioned on the edge part EDG.

In addition, the second adhesive dam AHD2-3 may be disposed detachedly from the edge part EDG in FIG. 14. The second adhesive dam AHD2-3 may interrupt flow of the adhesive layer AHL before curing. Therefore, the inclination degree of the inclined surface formed outside of the adhesive group AHG-4 may be large.

Accordingly, a larger area of the display area DA may be set, and the non-display area NDA may become narrower. In addition, light emitted from near a periphery of the display substrate DPS may be more normally provided to the outside.

As a result, even when the first adhesive dam AHD1 and the second adhesive dam AHD2-3 are not positioned adjacent to the edge part EDG, the adhesive group AHG-4 may facilitate an increase in an area of the display area DA and narrow non-display area NDA. In addition, light emitted from near a periphery of the display module DPM may be more normally provided to the outside.

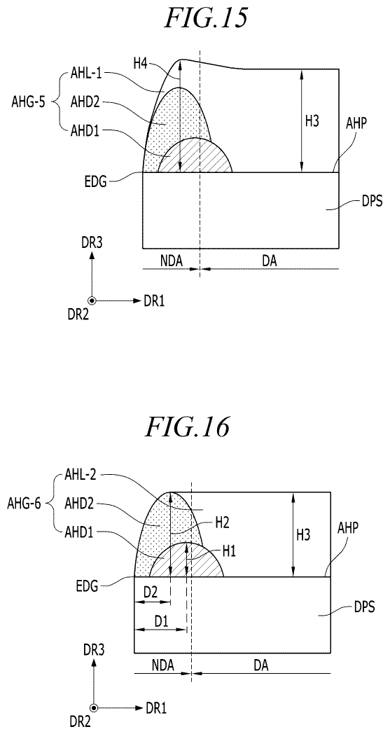

FIG. 15 is an exemplary magnified view of a portion marked with AA shown in FIG. 2 by omitting a window member WP. Referring to FIG. 15, a height of a portion of the adhesive group AHG-5 overlapping with the non-display area NDA may be a fourth height H4. In addition, the fourth height H4 may be greater than the third height H3, which is a height of a portion of the adhesive group AHG-5 overlapping with the display area DA.

In FIG. 15, the adhesive layer AHL-1 may be disposed having an upper surface having the fourth height H4 in the non-display aera NDA and the third height in the display area DA. For example, there may be a range where the adhesive group AHG-5 has the fourth height H4 due to a surface tension and surface energy of the adhesive layer AHL-1 before curing.

Meanwhile, the adhesive group AHG-5 may be elastic. Therefore, even when a range where the adhesive group AHG-5 has the fourth height H4 is formed, the adhesive group AHG-5 and the window member WP may be closely attached.

In addition, during attaching the adhesive group AHG-5 and the window member WP, a range where the adhesive group AHG-5 has the fourth height H4 may be pushed towards the edge part EDG. Furthermore, while pushing the range where the adhesive group AHG-5 has the fourth height H4 towards the edge part EDG, an inclination degree of an inclined surface formed outside of the adhesive group AHG-5 may become larger. In addition, the adhesive group AHG-5 and the window member WP may make contact over a larger area. Therefore, an area of the display area DA may be increased for a window member WP of a given size, and the non-display area NDA may become narrower. In addition, light emitted from near a periphery of the display substrate DPS may be more normally provided to the outside. For example, edge distortions may be reduced.

As a result, the adhesive layer AHL-1 may be disposed so that even when a height of a portion of the adhesive group AHG-5 overlapping with the non-display area NDA is greater than a height of a portion overlapping with the display area DA, the adhesive group AHG-5 may facilitate an increase in an area of the display area DA and a narrow non-display area NDA. In addition, light emitted from near a periphery of the display module DPM may be more normally provided to the outside. For example, edge distortions may be reduced.

FIG. 16 is an exemplary magnified view of a portion marked with AA shown in FIG. 2 by omitting a window member WP. Referring to FIG. 16, the second height H2 and the third height H3 may be the same.

In FIG. 16, the adhesive layer AHL-2 may be disposed on a side of the first adhesive dam AHD1 and the second adhesive dam AHD2. Herein, a portion of the adhesive layer AHL-2 may overlap the non-display area NDA and may expose at least a portion of the first adhesive dam AHD1 and the second adhesive dam AHD2. Therefore, the second height H2 and the third height H3 may be the same.

When the second height H2 and the third height H3 are the same, an inclination degree of an inclined surface formed outside of the adhesive group AHG-6 may therefore become greater due to the first adhesive dam AHD1 and the second adhesive dam AHD2. Accordingly, a larger area of the display area DA may be set, and the non-display area NDA may become narrower. In addition, light emitted from near a periphery of the display substrate DPS may be more normally provided to the outside. For example, edge distortions may be reduced.

As a result, less adhesive layers AHL-2 may be disposed so that even when the second height H2 and the third height H3 are the same, the adhesive group AHG-6 may facilitate an increase in an area of the display area DA and narrow non-display area NDA. In addition, light emitted from near a periphery of the display module DPM may be more normally provided to the outside. For example, edge distortions may be reduced.

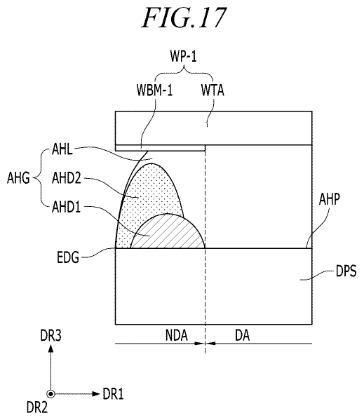

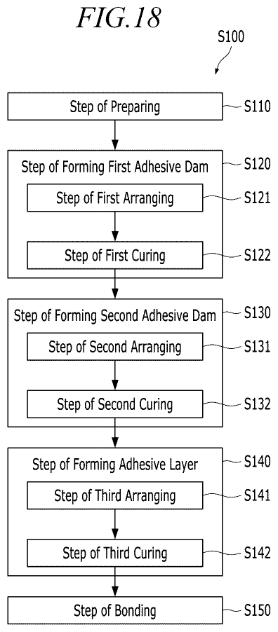

FIG. 17 is an exemplary magnified view of a portion marked with AA shown in FIG. 2.

Referring to FIG. 17, the first adhesive dam AHD1 and the second adhesive dam AHD2 of the present disclosure may entirely overlap with the light-blocking part WBM-1. In addition, the first adhesive dam AHD1 and the second adhesive dam AHD2 may not overlap with the display area DA.

Accordingly, light emitted from the display area DA may not pass through an interface disposed among the first adhesive dam AHD1, the second adhesive dam AHD2, and/or the adhesive layer AHL. The first adhesive dam AHD1, the second adhesive dam AHD2, and the adhesive layer AHL may have different degrees of cure. Therefore, the first adhesive dam AHD1, the second adhesive dam AHD2, and the adhesive layer AHL may have different optical properties.

Therefore, a shape of the light-blocking part WBM-1 may be controlled so that the adhesive dam AHD1 and the second adhesive dam AHD2 may entirely overlap with the non-display area NDA. Therefore, light emitted from near a periphery of the display substrate DPS may be more normally provided to the outside. For example, edge distortions may be reduced.

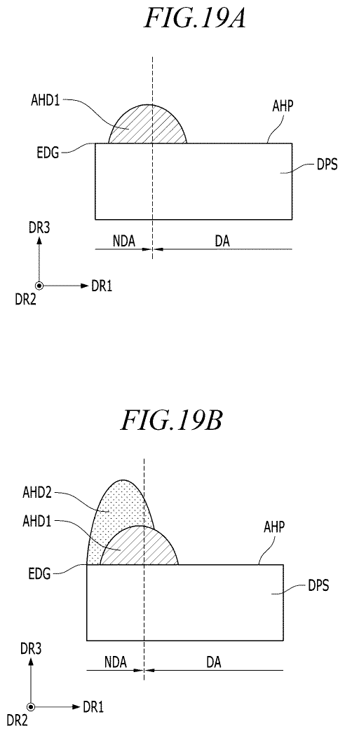

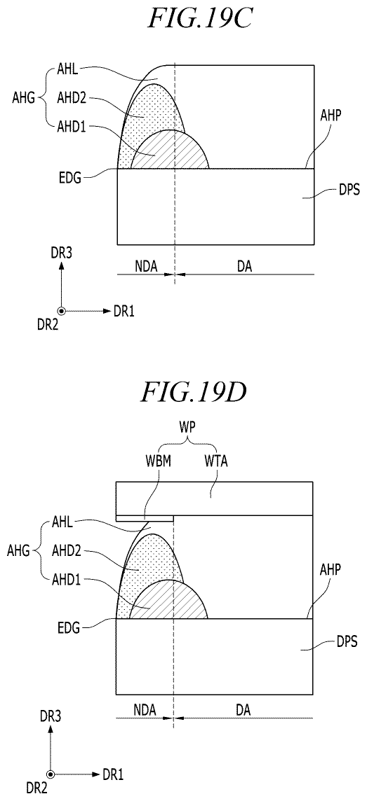

FIG. 18 is an exemplary flow diagram of a manufacturing method S100 of an electronic device according to an embodiment of the present disclosure. Each of FIGS. 19A through 19D is a schematic cross-sectional view of a step of a manufacturing method according to an embodiment of the present disclosure. Referring to FIG. 18 and FIGS. 19A through 19D, a manufacturing method of an electronic device according to an embodiment of the present disclosure is explained. Same figure numerals as in FIGS. 1 through 8 are added, and detailed descriptions thereof may be omitted or simplified.

Referring to FIG. 18, a manufacturing method S100 of an electronic device according to the present disclosure may include a step of preparing S110, a step of forming a first adhesive dam S120, a step of forming a second adhesive dam S130, a step of forming an adhesive layer S140 and a step of bonding S150. In addition, the electronic device manufactured through the manufacturing method of an electronic device S100 may be the display device DD.

Referring to FIG. 18 and FIG. 19A, in the step of preparing S110, a display substrate DPS including a display panel DP defined with a display area DA and a non-display area NDA surrounding the display area DA may be prepared.

The step of forming a first adhesive dam S120 may include a step of first arranging S121 and a step of first curing S122. In addition, in the step of forming a first adhesive dam S120, a first adhesive dam AHD1 may be formed on the display substrate DPS.

In the step of first arranging S121, a first adhesive dam AHD1 having at least a portion overlapping with the non-display area NDA and including a photocurable material may be disposed. In the step of first arranging S121, a viscosity of the first adhesive dam AHD1 may be between about 5 cP (centipoise) and about 40 cP. For example, a viscosity of an optically clear resin may be about 12 cP at a room temperature. In addition, the first adhesive dam AHD1 may be disposed by spraying on the display substrate DDPS. For example, the first adhesive dam AHD1 may be disposed by spraying through an ink jet method.

In the step of first curing S122, light is irradiated on the first adhesive dam AHD1 so that the first adhesive dam AHD1 is cured. In the step of first curing S122, the first adhesive dam AHD1 may be pre-cured.

Referring to FIG. 18 and FIG. 19B, the step of forming a second adhesive dam S130 may include a step of second arranging S131 and a step of second curing S132. In addition, in the step of forming a second adhesive dam S130, a second adhesive dam AHD2 may be formed on the display substrate DPS.

In the step of second arranging S131, a second adhesive dam AHD2 having at least a portion overlapping with the non-display area NDA and including a photocurable material may be disposed. In the step of second arranging S131, a viscosity of the second adhesive dam AHD2 may be between about 5 cP and about 40 cP at a room temperature. In addition, the second adhesive dam AHD2 may be disposed by spraying on the display substrate DPS. For example, the second adhesive dam AHD2 may be disposed by spraying through an ink jet method.

In the step of second curing S132, light may be irradiated on the second adhesive dam AHD2 so that the second adhesive dam AHD2 is cured. In the step of second curing S132, the second adhesive dam AHD2 may be pre-cured.

Meanwhile, while the second adhesive dam AHD2 is cured, the first adhesive dam AHD1 may be further cured.

Referring to FIG. 18 and FIG. 19C, the step of forming an adhesive layer S140 may include a step of third arranging S141 and a step of third curing S142. In addition, in the step of forming an adhesive layer S140, an adhesive slayer AHL may be formed on the display substrate DPS.

In the step of third arranging S141, an adhesive layer overlapping with the display area DA and including a photocurable material may be disposed. In the step of third arranging S141, a viscosity of the adhesive layer AHL may be between about 5 cP and about 40 cP at a room temperature. In addition, the adhesive layer AHL may be disposed by spraying on the display substrate DPS. For example, the adhesive layer AHL may be disposed by spraying through an ink jet method.

In the step of third curing S142, light may be irradiated on the adhesive layer AHL so that the adhesive layer AHL is cured. In the step of third curing S142, the adhesive layer AHL may go through a main curing. That is, an amount of light irradiated in the step of third curing S142 may be more than an amount of light irradiated in the step of first curing S122 and the step of second curing S132. For example, the amount of light irradiated in the step of third curing S142 may be 5 times to 7 times the amount of light irradiated in the step of first curing S122 and the step of second curing S132. In addition, while the adhesive layer AHL is cured, the first adhesive dam AHD1 and the second adhesive dam AHD2 may be further cured.

Furthermore, in the step of third curing S142, light may be irradiated on the adhesive layer AHL multiple times. In addition, while light is irradiated multiple times in the step of third curing S142, a different amount of light may be irradiated. For example, in the step of third curing S142, light with the same amount as in the step of first curing S122 and the step of second curing S132 may be irradiated on the adhesive layer AHL and light with an amount of light 4 times to 6 times the amount of light in the step of first curing S122 and the step of second curing S132 may be subsequently irradiated on the adhesive layer AHL again.

Referring to FIG. 18 and FIG. 19D, in the step of bonding S150, a window member WP may be disposed on the first adhesive dam AHD1, the second adhesive dam AHD2 and the adhesive layer AHL. As a result, the display substrate DPS and the window member WP may be attached with an adhesive group AHG therebetween.

Hereinafter, a shape of the adhesive group AHG according to an comparative example of the present disclosure is explained.

In comparative examples of the present disclosure, a method of arranging the first adhesive dam AHD1 and a method of arranging the second adhesive dam AHD2 may be controlled. More particularly, the first height H1, the first distance D1, the second height H2 and the second distance D2 may be controlled. In addition, the third height H3 of the adhesive layer AHL may be set to about 200 μm. Furthermore, the inclination degree of the inclined surface formed outside of the adhesive group AHG may be demonstrated. The inclination degree may be calculated by dividing the height of the inclined surface, e.g., the third height H3, by a horizontal distance of the inclined surface.

### Comparative Examples

| | First | First | | | | |
|---|---|---|---|---|---|---|
| | height | distance | | Second | Second | Inclination |
| | H1 | D1 | | height H2 | distance D2 | degree |
| Example 1 | 67 μm | 1 | mm | 182 μm | 0.6 mm | 25% |
| Example 2 | 52 μm | 1.6 | mm | 191 μm | 0.8 mm | 25% |
| Example A | 54 μm | 1 | mm | 124 μm | 0.7 mm | Less than |
| | | | | | | 10% |
| Example B | 51 μm | 1.2 | mm | 131 μm | 0.7 mm | Less than |
| | | | | | | 10% |
| Example C | 61 μm | 1.5 | mm | 146 μm | 0.8 mm | Less than |
| | | | | | | 10% |
| Example D | 76 μm | 2.7 | mm | 250 μm | 1.5 mm | 12% |

In the comparative examples of the present disclosure, when the first height H1 is between about 0.2 times and about 0.4 times the third height, and the second height H2 is between about 0.8 times and about 1.0 times the third height as in Example 1 and Example 2, the inclination degree may be about 25%, which may be favorable.

Meanwhile, when the second height H2 was less than about 0.8 times the third height H3 as in Examples B and C, the inclination degree may be less than about 10%, which may be insufficient.

In addition, when the second height H2 is greater than the third height H3 as in Example D, the inclination degree may be about 12%, which may be insufficient.

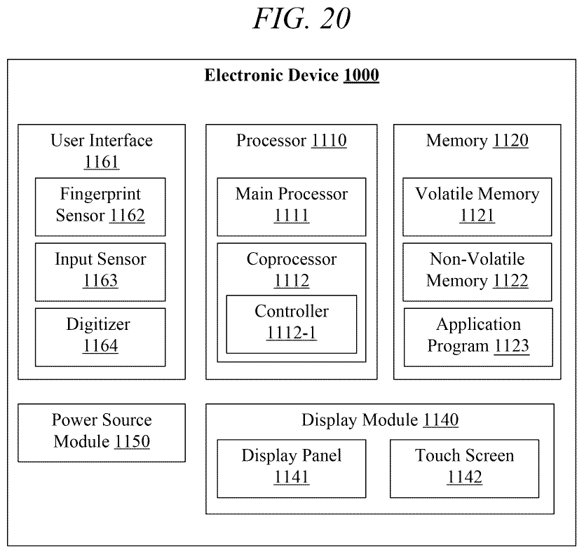

FIG. 20 is a diagram illustrating an electronic device according to an embodiment of the present invention. Referring to FIG. 20, the electronic device 1000 according to one embodiment of the present invention may output various information (e.g., images, text, music, etc.) through a display module 1140, which, for example, may correspond to the display device DD shown in FIG. 1. When a processor 1110 executes an application stored in a memory 1120, the display module 1140 may provide application information to a user through a display panel 1141. The display panel 1141 may be the same as the display panel DP described elsewhere herein.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction. The touch screen 1142 may be the same as the input sensor circuit ISC described elsewhere herein.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device DD shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

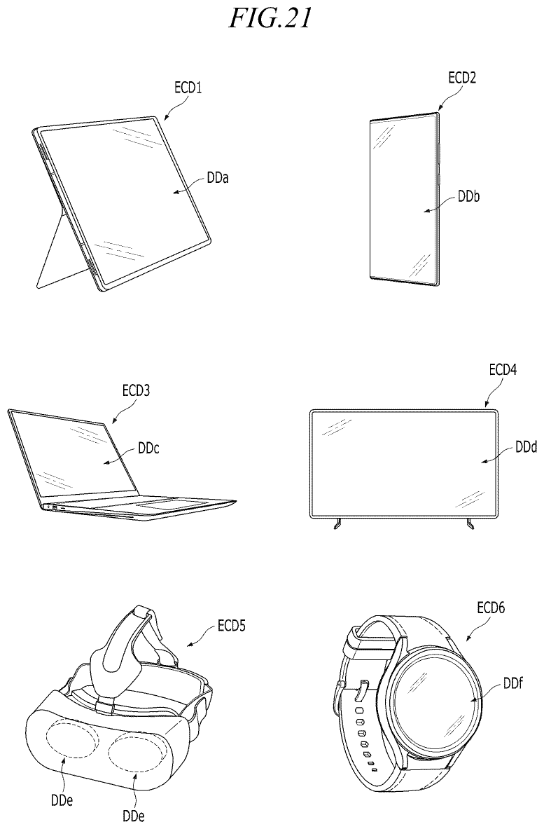

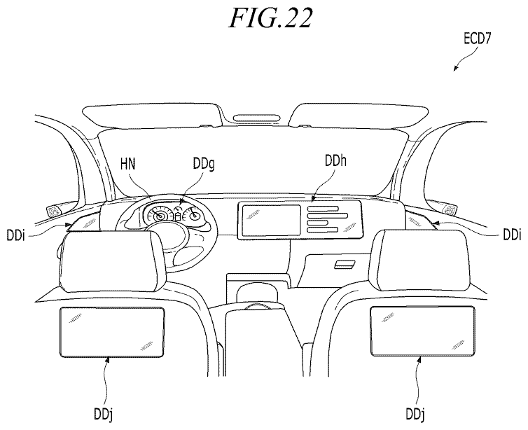

FIG. 21 and FIG. 22 are diagrams illustrating electronic devices to which the display device according to an embodiment of the present disclosure is applied.

Referring to FIG. 21, a first electronic device ECD1 is depicted as a tablet PC including a first display device DDa. A second electronic device ECD2 is depicted as a portable terminal including a second display device DDb. A third electronic device ECD3 is depicted as a notebook computer including a third display device DDc. A fourth electronic device ECD4 is depicted as a TV including a fourth display device DDd. A fifth electronic device ECD5 is depicted as a head-mounted display device including a fifth display device DDe. A sixth electronic device ECD6 is depicted as a digital watch including a sixth display device DDf.

Referring to FIG. 22, a seventh electronic device ECD7 is depicted as a vehicle including seventh through tenth display devices DDg−DDj. Although an automobile is exemplified as the seventh electronic device ECD7, the present disclosure is not limited thereto and may include various types of transportation means, such as bicycles, motorcycles, trains, ships, and airplanes.

The seventh display device DDg may be placed in front of the steering wheel HN within the driver's field of view and may be used to display dashboard information such as vehicle speed. The eighth display device DDh may be separate from the seventh display device DDg and placed on the vehicle's dashboard to display control interfaces, audio, temperature, road conditions, and videos. The ninth display device DDi may be placed at the driver and passenger side mirrors and may be utilized as a digital side mirror. The ninth display device DDi may display video captured from the vehicle's exterior. The tenth display device DDj may be placed behind the driver and passenger seats and may display contents, such as videos, to the rear seat passengers.

At least one of the first through tenth display devices DDa−DDj may include the display device DD described with reference to FIG. 1, FIG. 2, FIGS. 3A to 3C, FIGS. 4 to 9, and FIGS. 10A to 10D At least one of the first through tenth display devices DDa−DDj may also include the display device DD described with reference to FIG. 11 to FIG. 17.

The display devices according to embodiments of the present disclosure are not limited to the electronic devices shown in FIG. 21 and FIG. 22 and may also be applied to a variety of electronic devices, such as printers, telephones, wearable devices, digital cameras, camcorders, viewfinders, 3D displays, video walls comprising tiled displays, theaters, signage, and the like.

While example embodiments of the present disclosure have been described herein, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that embodiments are not intended to restrict the present disclosure thereto and that every technical idea within the appended claims and their equivalents is interpreted to be included in the scope of the present disclosure.

What is claimed is:

1. An electronic device comprising:
a display panel defined with a display area and a non-display area surrounding at least a portion of the display area;
an adhesive group disposed on the display panel; and
a window member disposed on the adhesive group, wherein the adhesive group comprises:
a first adhesive dam having at least a portion overlapping with the non-display area;
a second adhesive dam covering a first portion of the first adhesive dam and having at least a portion overlapping with the non-display area; and
an adhesive layer covering the first portion of the first adhesive dam and a portion of the second adhesive dam and overlapping with the display area.

2. The electronic device of claim 1, wherein the second adhesive dam is disposed on an outer surface of the first adhesive dam disposed away from the display area.

3. The electronic device of claim 2, wherein the second adhesive dam exposes a second portion of the first adhesive dam.

4. The electronic device of claim 3, wherein the first adhesive dam has a first height,
wherein the second adhesive dam has a second height that is greater than the first height, and
wherein the adhesive layer has a third height that is equal to or greater than the second height.

5. The electronic device of claim 4,
wherein the first height is between about 0.2 times and about 0.4 times the third height and
wherein the second height between about 0.8 times and about 1.0 times the third height.

6. The electronic device of claim 3, wherein a contact angle of the second adhesive dam is greater than a contact angle of the first adhesive dam.

7. The electronic device of claim 1, wherein each of the first adhesive dam, the second adhesive dam and the adhesive layer comprises a photocurable material,
wherein the first adhesive dam has a first degree of cure,
wherein the second adhesive dam has a second degree of cure that is less than the first degree of cure, and
wherein the adhesive layer has a third degree of cure that is less than the second degree of cure.

8. The electronic device of claim 7, wherein the first degree of cure between about 95% and about 99%,
wherein the second degree of cure is between about 93% and about 94%, and
wherein the third degree of cure is between about 91% and about 92%.

9. The electronic device of claim 7, wherein a degree of cure of a portion of the adhesive layer overlapping with the display area is substantially the same as a degree of cure of a portion overlapping with the non-display area.

10. The electronic device of claim 1, wherein each of the first adhesive dam, the second adhesive dam, and the adhesive layer comprises a pressure sensitive adhesive.

11. The electronic device of claim 1, wherein the window member comprises:
a light transmission part overlapping with the adhesive layer and configured to transmit light emitted from the display panel; and
a light blocking part overlapping with the first adhesive dam and the second adhesive dam and configured to block light emitted from the display panel.

12. An electronic device comprising:
a display panel defined with a display area and a non-display area surrounding at least a portion of the display area;
an adhesive group disposed on the display panel; and
a window member disposed on the adhesive group, wherein the adhesive group comprises:
a first adhesive dam extending along a boundary part between the display area and the non-display area;
a second adhesive dam disposed in at least a portion of the non-display area, covering a first portion of the first adhesive dam, and extending along the first adhesive dam; and
an adhesive layer having at least a portion surrounded by the first adhesive dam and the second adhesive dam and covering the first portion of the first adhesive dam and a portion of the second adhesive dam.

13. The electronic device of claim 12, wherein the second adhesive dam is disposed on an outer surface of the first adhesive dam disposed away from the display area, and
wherein the second adhesive dam exposes a second portion of the first adhesive dam.

14. The electronic device of claim 13, wherein the first adhesive dam has a first height,
wherein the second adhesive dam has a second height that is greater than the first height, and
wherein the adhesive layer has a third height that is greater than the second height.

15. The electronic device of claim 12, wherein a contact angle of the second adhesive dam is greater than a contact angle of the first adhesive dam.

16. The electronic device of claim 12, wherein each of the first adhesive dam, the second adhesive dam and the adhesive layer comprises a photocurable material,
wherein the first adhesive dam has a first degree of cure,
wherein the second adhesive dam has a second degree of cure that is less than the first degree of cure, and
wherein the adhesive layer has a third degree of cure that is less than the second degree of cure.

17. The electronic device of claim 12, wherein each of the first adhesive dam, the second adhesive dam and the adhesive layer comprises a pressure sensitive adhesive.

18. A manufacturing method of an electronic device, comprising:
providing a display substrate comprising a display panel defined with a display area and a non-display area surrounding at least a portion of the display area;
disposing a first adhesive dam having a portion overlapping with the non-display area and comprising a photocurable material;
performing a first curing of the first adhesive dam;
disposing a second adhesive dam covering a portion of the first adhesive dam, having at least a portion overlapping with the non-display area and comprising a photocurable material;
performing a second curing of the second adhesive dam and the first adhesive dam;
forming an adhesive layer covering the portion of the first adhesive dam and a portion of the second adhesive dam, overlapping with the display area and comprising a photocurable material;
performing a third curing of the adhesive layer, the second adhesive dam and the first adhesive dam; and
bonding a window member to the display substrate using the first adhesive dam, the second adhesive dam, and the adhesive layer.

19. The manufacturing method of an electronic device of claim 18, wherein an amount of light irradiated in performing the third curing is greater than an amount of light irradiated in performing the first curing and an amount of light irradiated in performing the second curing.

20. The manufacturing method of an electronic device of claim 18, wherein a viscosity of the first adhesive dam, as disposed, is between about 5 cP (centipoise) and about 40 cP,
wherein a viscosity of the second adhesive dam, as disposed, is between about 5 cP and about 40 cP, and
wherein a viscosity of the adhesive layer, as formed, is between about 5 cP and about 40 cP.
